(19) United States
(12) Patent Application Publication
(10) Pub. No.: US 2016/0293512 A1
(43) Pub. Date: Oct. 6, 2016

(54) ELECTRONIC DEVICE WITH DUMMY IC DIE AND RELATED METHODS

(71) Applicant: STMICROELECTRONICS PTE LTD, Singapore (SG)

(72) Inventors: Yiyi MA, Singapore (SG); Kim-Yong GOH, Singapore (SG); Xueren ZHANG, Singapore (SG)

(21) Appl. No.: 14/674,156

(22) Filed: Mar. 31, 2015

(51) Int. Cl. H01L 23/367; H01L 23/00; H01L 25/00; H01L 27/18

(52) U.S. Cl. CPC H01L 23/367; H01L 27/18; H01L 24/32; H01L 25/50; H01L 24/83; H01L 2924/351

(57) ABSTRACT

An electronic device may include a substrate, an active IC die above the substrate, and a dummy IC die above the active IC die. The electronic device may include a first adhesive layer between the active IC die and the dummy IC die, and a heat sink layer above the dummy IC die and extending laterally outwardly to define a gap between the substrate and opposing portions of the heat sink layer.

### TECHNICAL FIELD

The present disclosure relates to the field of integrated circuit devices, and, more particularly, to packaging of integrated circuit devices and related methods.

### BACKGROUND

In electronic devices with integrated circuits (ICs), the ICs are typically mounted onto circuit boards. In order to electrically couple connections between the circuit board and the IC, the IC is typically “packaged.” The IC packaging usually provides a small encasement for physically protecting the IC and provides contact pads for coupling to the circuit board. In some applications, the packaged IC may be coupled to the circuit board via solder bumps.

Referring to FIG. 1, a typical ball grid array (BGA) electronic device 100 is now described. The electronic device 100 includes a substrate 114, an IC 117 on the substrate, and a heat sink layer 111 over the substrate and on the IC. The electronic device 100 includes stiffeners 122 between the heat sink layer 111 and the substrate 114. The electronic device 100 defines a gap 121 between the substrate 114 and the heat sink layer 111.

Referring to FIG. 2, another typical ball grid array (BGA) electronic device 200 is now described. The electronic device 200 includes a substrate 214, an IC 217 on the substrate, and a heat sink layer 211 over the substrate and on the IC. The electronic device 200 defines a gap 221 between the substrate 214 and the heat sink layer 211. This heat sink layer 211 includes a raised portion over the IC 217.

Referring to FIG. 3, yet another typical ball grid array (BGA) electronic device 300 is now described. The electronic device 300 includes a substrate 314, an IC 317 on the substrate, and a heat sink layer 311 over the substrate and on the IC. The electronic device 300 defines a gap 321 between the substrate 314 and the heat sink layer 311. This heat sink layer 311 includes legs coupled to the substrate 314 and for defining the gap 321. Since each of these prior art electronic devices includes interfaces between different materials, coefficient of thermal expansion (CTE) mismatch may cause reliability issues.

### SUMMARY

Generally speaking, an electronic device may include a substrate, an active IC die above the substrate, and a dummy IC die above the active IC die. The electronic device may comprise a first adhesive layer between the active IC die and the dummy IC die, and a heat sink layer above the dummy IC die and extending laterally outwardly therefrom to define a gap between the substrate and opposing portions of the heat sink layer.

Additionally, the electronic device may further comprise an underfill layer between the active IC die and the substrate. The heat sink layer may comprise a raised hat portion above the dummy IC die. For example, the gap has an L shape. The substrate may have a rectangular shape larger than the active IC die, and the active IC die may be positioned at a corner of the substrate.

In some embodiments, the electronic device may further comprise a thermal interface layer between the heat sink layer and the dummy IC die. The electronic device may further comprise at least one component in the gap and carried by the substrate. The active IC die and the dummy IC die may have a same shape. For example, the active IC die and dummy IC die may each comprise silicon. The electronic device may also comprise a second adhesive layer between the substrate and the heat sink layer.

Another aspect is directed to a method for making an electronic device. The method may include mounting an active IC die above a substrate, and mounting a dummy IC die above the active IC die using a first adhesive layer between the active IC die and the dummy IC die. The method may include mounting a heat sink layer above the dummy IC die and extending laterally outwardly therefrom to define a gap between the substrate and opposing portions of the heat sink layer.

### BRIEF DESCRIPTION OF THE DRAWINGS

FIGS. 1-3 are schematic perspective views of electronic devices, according to the prior art.

FIG. 4 is a schematic perspective view of an electronic device, according to the present disclosure.

FIG. 5 is a schematic side view of a portion of the electronic device of FIG. 4.

### DETAILED DESCRIPTION

The present disclosure will now be described more fully hereinafter with reference to the accompanying drawings, in which several embodiments of the invention are shown. This present disclosure may, however, be embodied in many different forms and should not be construed as limited to the embodiments set forth herein. Rather, these embodiments are provided so that this disclosure will be thorough and complete, and will fully convey the scope of the present disclosure to those skilled in the art. Like numbers refer to like elements throughout.

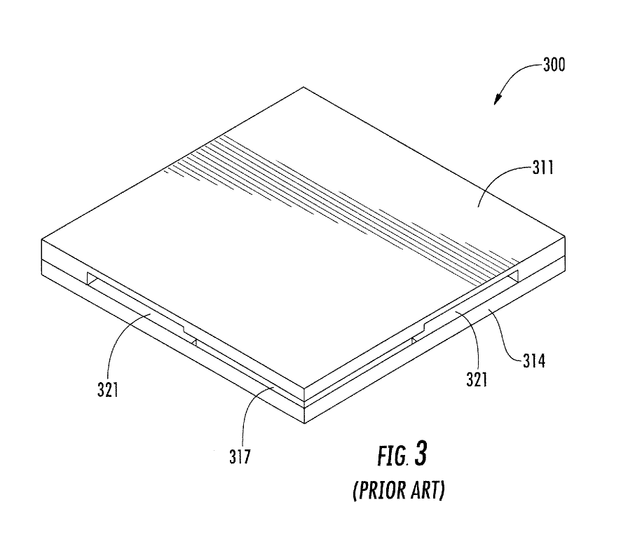

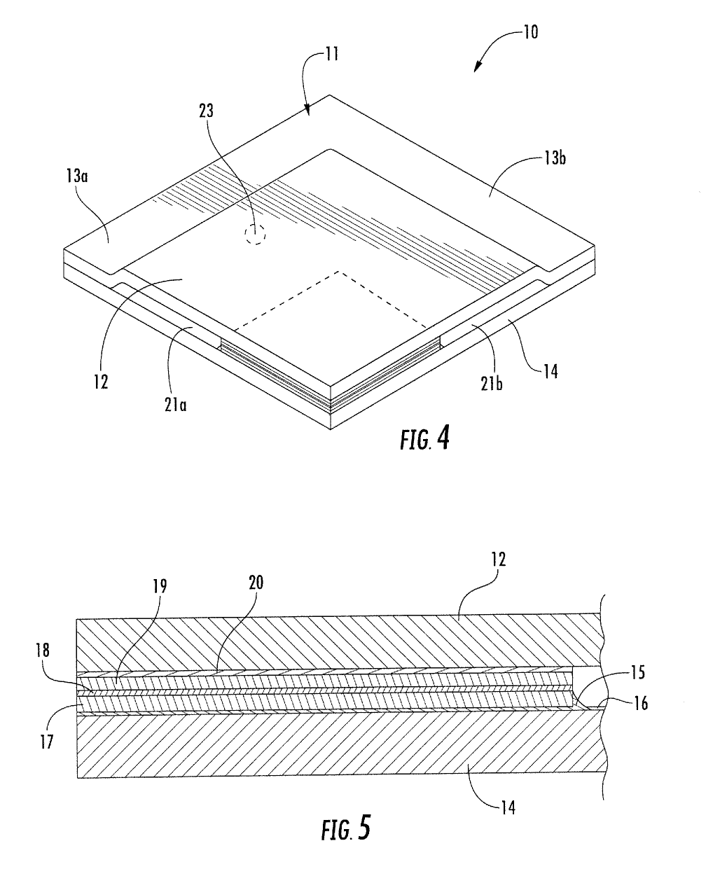

Referring now to FIGS. 4-5, an electronic device 10 according to the present disclosure is now described. The electronic device 10 illustratively includes a substrate 14. For example, the substrate 14 may comprise a dielectric layer (e.g. glass, circuit board layer, bonding core layer), and a plurality of electrically conductive traces, vias, and pads carried by the dielectric layer.

The electronic device 10 illustratively includes an active IC die 17 above the substrate 14, a dummy IC die 19 above the active IC die (shown with dashed lines in FIG. 4), and a first adhesive layer 18 between the active IC die and the dummy IC die. In this illustrated embodiment, the active IC die 17 comprises a flip chip BGA device. In other words, although not shown, the substrate 14 carries a plurality of BGA contacts on the surface opposite the active IC die 17. For example, the active IC die 17 and dummy IC die 19 may each comprise silicon, but other semiconductor materials can be used. The active IC die 17 may comprise a “thinned down” die in some embodiments.

Also, the active IC die 17 may comprise circuitry, and a plurality of electrically conductive bond pads. The dummy IC die 19 may also comprise non-functional circuitry, and a plurality of electrically conductive bond pads, or in some embodiments, the dummy IC die 19 may comprise a bare semiconductor substrate. Additionally, the electronic device 10 illustratively includes an underfill layer 15 between the active IC die 17 and the substrate 14.

The first adhesive layer 18 may include a low stress adhesive material, i.e. a stress absorbing material having a low modulus of elasticity and superior elongation properties. The active IC die 17 and the dummy IC die 19 may have a same shape, in the illustrated embodiment, a square shape.

The electronic device 10 illustratively includes a heat sink layer 11 above the dummy IC die 19 and extending laterally outwardly therefrom to define a gap 21a-21b between the substrate 14 and opposing portions of the heat sink layer. The heat sink layer 11 may comprise copper, for example, or any effective thermally conductive material. In the illustrated embodiment, the electronic device 10 illustratively includes a thermal interface layer 20 between the heat sink layer 11 and the dummy IC die 19, and an electronic component (e.g. a capacitor or a resistor) 23 in the gap 21a-21b and carried by the substrate 14.

As perhaps best seen in FIG. 4, the heat sink layer 11 may comprise a raised hat portion 12 above the dummy IC die 19, and lower portions 13a-13b bonded to the substrate 14. In particular, the electronic device 10 illustratively includes a second adhesive layer 16 between the substrate 14 and the lower portions 13a-13b of the heat sink layer 11. In the illustrated embodiment, the gap 21a-21b has an “L” shape (shown via the dashed lines, indicating placement of the active and dummy IC dies 17, 19 that define the gap, in FIG. 4).

Also, the substrate 14 has a rectangular shape larger than the active IC die 17, and the active IC die is be positioned at a corner of the substrate. The active IC and dummy IC dies 17, 19 illustratively have square shapes aligned with the corner of the substrate 14. The gap 21a-21b extends along the edges of the active IC and dummy IC dies 17, 19 opposite the outer edges aligned with the corner of the substrate 14.

In some embodiments, the electronic device 10 may include a housing or encapsulation material surrounding the substrate 14. The housing may comprise a plastic or metallic container, for example.

Another aspect is directed to a method for making an electronic device 10. The method may include mounting an active IC die 17 above a substrate 14, and mounting a dummy IC die 19 above the active IC die using a first adhesive layer 18 between the active IC die and the dummy IC die. The method may include positioning a heat sink layer 11 above the dummy IC die 19 and extending laterally outwardly therefrom to define a gap 21a-21b between the substrate 14 and opposing portions of the heat sink layer.

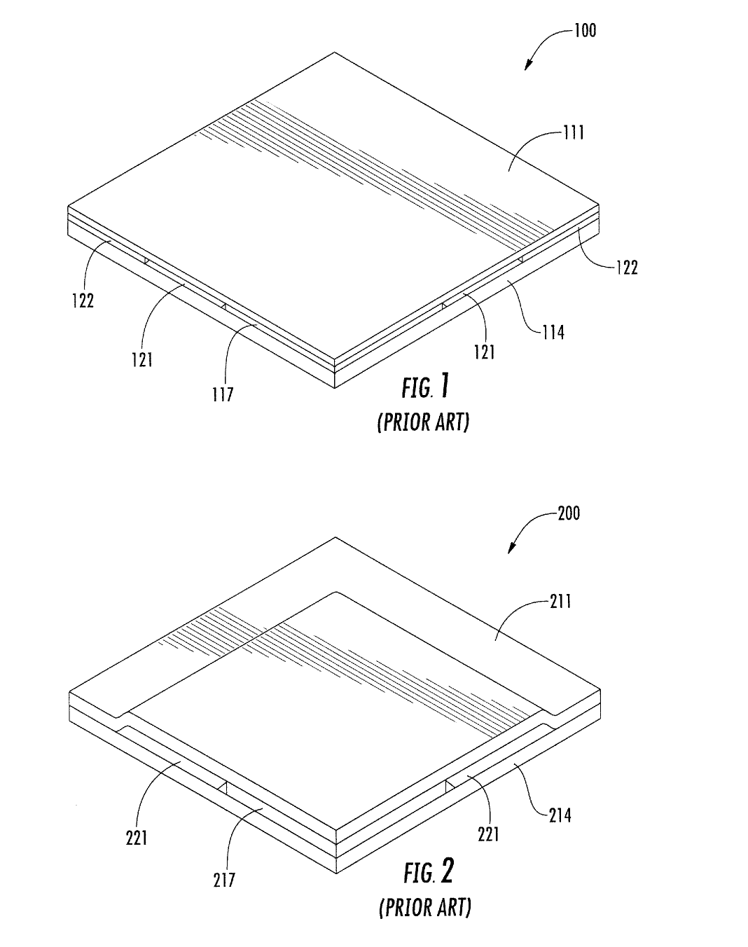

In the prior art devices of FIGS. 1-3, the adjacent different materials lead to CTE mismatch issues. This CTE mismatch may lead to warping and stress when the electronic devices 100, 200, 300 are exposed to heat. The CTE mismatch can lead to reduced board level reliability (BLR), which is undesirable. The electronic device 100 (FIG. 1, two-piece copper (2PC) heat sink layer 111) provides an approach to CTE mismatch, but this approach is costly to manufacture.

On the other hand, the electronic device 200 (FIG. 2, single piece copper (SPC) heat sink layer 211) provides an approach to CTE mismatch that is less expensive, but still subjects the IC 217 to high levels of stress and warping (See Table 1). Also, the dual cavity flat approach of the electronic device 300 (FIG. 3) provides good performance, but is costly to manufacture.

Advantageously, the electronic device 10 may provide a cost effective approach that provides similar performance to the dual cavity flat approach. Also, the electronic device 10 allows used of a thinner active IC die 17 and the standard passive devices/electronic components 23. Indeed, a simulation shows that the electronic device's 10 performance is comparable to that of the dual cavity lid approach in terms of the warping and stress (See Table 1).

TABLE 1

| | Die thickness | | | |
|---|---|---|---|---|
| Leg | (μm) | Lid | Warpage (μm) | Stress (MPa) |
| 1 | 775 | SPC Hat | −97.0 | 72.9 |
| 2 | 300 | Dual Cavity Flat | −95.4 | 61.0 |
| 3 | 300 | SPC Hat with | −100.3 | 64.13 |
| | | Dummy Die | | |

Also, since the electronic device 10 may include a thinned down active IC die 17, the potential for warping and reduced BLR is mitigated. This is because of the CTE mismatch reduction due to reduced thickness. Nevertheless, in the prior art approaches, the addition of passive electronic components reduces the ability to thin the IC. The electronic device 10 disclosed herein provides an approach that allows for both the thinned active IC die 17 and passive electronic components 23. Also, by leveraging the dummy IC die 19 and the low stress first adhesive layer 18, the level of CTE mismatch in the electronic device 10 is reduced, particularly adjacent the active IC die 17.

Many modifications and other embodiments of the present disclosure will come to the mind of one skilled in the art having the benefit of the teachings presented in the foregoing descriptions and the associated drawings. Therefore, it is understood that the present disclosure is not to be limited to the specific embodiments disclosed, and that modifications and embodiments are intended to be included within the scope of the appended claims.

1. An electronic device comprising:
a substrate;
an active integrated circuit (IC) die above said substrate;
a dummy IC die above said active IC die;
a first adhesive layer between said active IC die and said dummy IC die; and
a heat sink layer above said dummy IC die and extending laterally outwardly therefrom to define an air gap between said substrate and opposing portions of said heat sink layer.

2. The electronic device of claim 1 further comprising an underfill layer between said active IC die and said substrate.

3. The electronic device of claim 1 wherein said heat sink layer comprises a raised hat portion above said dummy IC die.

4. The electronic device of claim 1 wherein the air gap has an L shape.

5. The electronic device of claim 1 wherein said substrate has a rectangular shape larger than said active IC die; and wherein said active IC die is positioned at a corner of said substrate.

6. The electronic device of claim 1 further comprising a thermal interface layer between said heat sink layer and said dummy IC die.

7. The electronic device of claim 1 further comprising at least one component in the air gap and carried by the substrate.

8. The electronic device of claim 1 wherein said active IC die and said dummy IC die have a same shape.

9. The electronic device of claim 1 wherein said active IC die and dummy IC die each comprises silicon.

10. The electronic device of claim 1 further comprising a second adhesive layer between said substrate and said heat sink layer.

11. An electronic device comprising:
a substrate;
an active integrated circuit (IC) die above said substrate;
a dummy IC die above said active IC die, said active IC die and said dummy IC die having a same shape;
a first adhesive layer between said active IC die and said dummy IC die;
a heat sink layer above said dummy IC die and extending laterally outwardly therefrom to define an air gap between said substrate and opposing portions of said heat sink layer, said heat sink layer comprising a raised hat portion above said dummy IC die; and
an underfill layer between said active IC die and said substrate.

12. The electronic device of claim 11 wherein the air gap has an L shape.

13. The electronic device of claim 11 wherein said substrate has a rectangular shape larger than said active IC die; and wherein said active IC die is positioned at a corner of said substrate.

14. The electronic device of claim 11 further comprising a thermal interface layer between said heat sink layer and said dummy IC die.

15. The electronic device of claim 11 further comprising at least one component in the air gap and carried by the substrate.

16. The electronic device of claim 11 wherein said active IC die and dummy IC die each comprises silicon.

17. A method for making an electronic device comprising:
mounting an active integrated circuit (IC) die above a substrate;
mounting a dummy IC die above the active IC die using a first adhesive layer between the active IC die and the dummy IC die; and
mounting a heat sink layer above the dummy IC die and extending laterally outwardly therefrom to define an air gap between the substrate and opposing portions of the heat sink layer.

18. The method of claim 17 further comprising forming an underfill layer between the active IC die and the substrate.

19. The method of claim 17 wherein the heat sink layer comprises a raised hat portion above the dummy IC die.

20. The method of claim 17 wherein the air gap has an L shape.

21. The method of claim 17 wherein the substrate has a rectangular shape larger than the active IC die;
and wherein the active IC die is positioned at a corner of the substrate.

22. The method of claim 17 further comprising forming a thermal interface layer between the heat sink layer and the dummy IC die.

23. An electronic device comprising:
a substrate;
an active integrated circuit (IC) die above said substrate;
a dummy IC die above said active IC die and being non-functional;
a first adhesive layer between said active IC die and said dummy IC die;
said active IC die, dummy IC die, and first adhesive layer having aligned boundaries; and
a heat sink layer above said dummy IC die and extending laterally outwardly therefrom to define a gap between said substrate and opposing portions of said heat sink layer.

24. The electronic device of claim 23 further comprising an underfill layer between said active IC die and said substrate.

25. The electronic device of claim 23 wherein said heat sink layer comprises a raised hat portion above said dummy IC die.

26. The electronic device of claim 23 wherein the gap has an L shape.
